(19) United States
(12) Patent Application Publication
(10) Pub. No.: US 2014/0147313 A1
(43) Pub. Date: May 29, 2014

(54) FAN DEVICE

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventors: PING-CHUAN DENG, Shenzhen (CN); AN-GANG LIANG, Shenzhen (CN); ZHENG-HENG SUN, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/706,340

(22) Filed: Dec. 5, 2012

(30) Foreign Application Priority Data
Nov. 26, 2012 (CN) 201210485611.0

(51) Int. Cl. H05K 7/20

(52) U.S. Cl. CPC H05K 7/20172
USPC 417/423.15; 417/423.14

(57) ABSTRACT

A fan device includes a board defining an opening, a fan assembly, and a fastener. Two installation pieces extend from the board at opposite sides of the opening, one of which defines a first through hole. The fan assembly is pivotably mounted between the installation pieces, and includes a fan and a frame receiving the fan. The frame includes a top wall, a bottom wall, and two sidewalls. One of the sidewalls adjacent to the installation piece defining the first through hole defines a first threaded hole. When the fan assembly is pivoted to allow the first through hole to align with the first threaded hole, the fastener extends through the first through hole and then is engaged in the first threaded hole, to make the fan assembly slant relative to the board.

### BACKGROUND

1. Technical Field

The present disclosure relates to a fan device.

2. Description of Related Art

Fan brackets are often installed to sides of server racks to dissipate heat generated by the servers. However, fans mounted to a fan bracket are often slanted relative to the fan bracket to generate even airflows, and the slanted fans require more space along one dimension. As a result, a server rack needs to be long enough to receive a whole fan bracket with the fans; otherwise parts of the slanted fans may stick out of the server rack and be broken easily in packaging and transportation, which is undesirable.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fan device including a plurality of fan assemblies and a plurality of fasteners.

FIG. 2 is a cross-sectional view of one of the fasteners of FIG. 1.

FIG. 3 is an assembled, isometric view of FIG. 1.

FIG. 4 is similar to FIG. 3, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

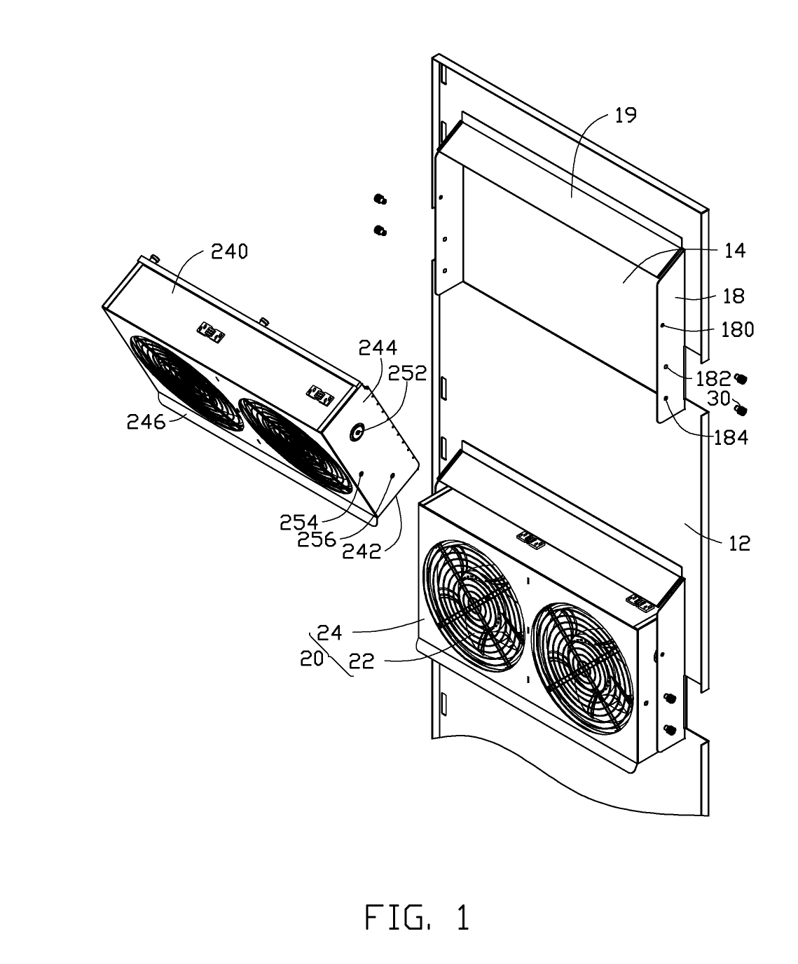

FIG. 1 shows an exemplary embodiment of a fan device. The fan device includes a board 12, a plurality of fan assemblies 20, and a plurality of fasteners 30.

The board 12 defines a plurality of spaced openings 14 arranged in a lengthwise direction of the board 12. Two installation pieces 18 perpendicularly extend forward from the board 12, at opposite sides of each opening 14. A cover 19 extends down and diagonally forward from the board 12, at a top side of each opening 14. Each installation piece 18 defines a pivot hole 180, a first through hole 182, and a second through hole 184 arranged in a lengthwise direction of the installation piece 18. Each installation piece 18 forms a slanted top end to contact a bottom of a corresponding one of opposite ends of the cover 19.

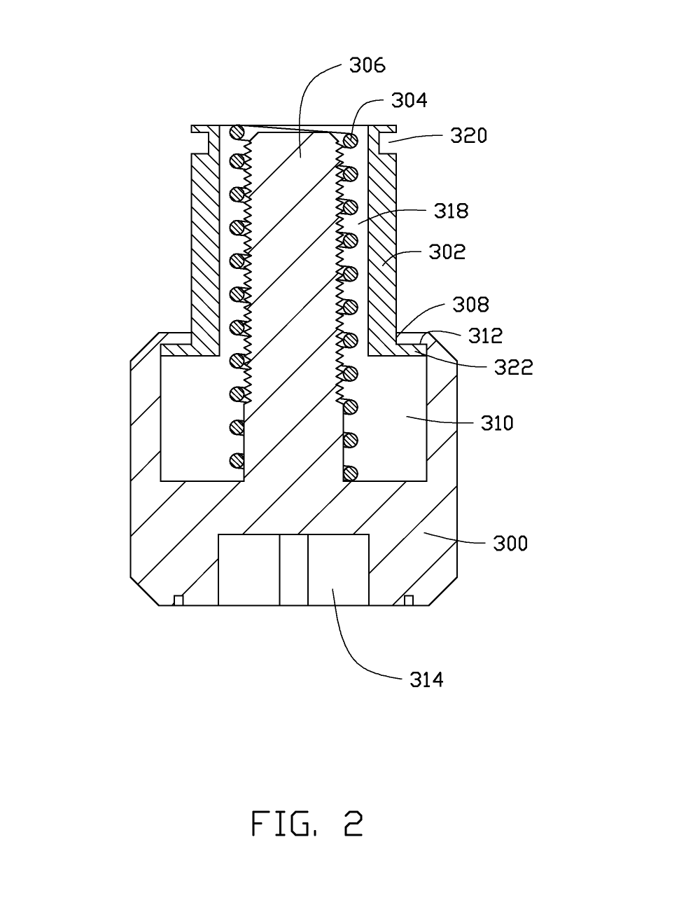

Referring to FIG. 2, each fastener 30 includes a head 300, a positioning pole 302, a spring 304, and a threaded pole 306. The head 300 defines an opening 308 in a first side, and a receiving space 310 communicating with the opening 308 and having a blind end. The receiving space 310 has a diameter less than a diameter of the opening 308; therefore, an annular step 312 is formed in the receiving space 310. A crisscross or a straight recess 314 is defined in a second side of the head 30 opposite to the first side. An antiskid portion (not shown) is formed on an outer surface of the head 30. The threaded pole 306 is connected to the blind end of the receiving space 310, and extends out of the opening 308. The positioning pole 302 defines a through slot 318 extending through opposite ends of the positioning pole 302. A latching portion 320 is formed at a first end of the positioning pole 302. An annular protrusion 322 protrudes from a second end of a circumference of the positioning pole 302 opposite to the latching portion 320. The second end of the positioning pole 302 is extended into the receiving space 310 to allow the protrusion 322 abuts the step 312, thereby slidably mounting the positioning pole 302 to the head 300. The through slot 318 is communicated with the opening 308 and the receiving space 310, and the threaded pole 306 extends through the through slot 318.

The spring 304 is fitted around the threaded pole 306. A first end of the spring 304 is fixed to the blind end of the receiving space 310. A second end of the spring 304 extends out of the opening 308 and is received in the through slot 318.

The fasteners 30 are respectively mounted to the first and second through holes 182 and 184. The positioning poles 302 are respectively extended through the first through hole 182 and the second through hole 184, to allow the corresponding latching portions 320 to latch with the board 12, thereby mounting the fastener 30 to the board 12 and preventing the fastener 30 from missing.

In this embodiment, the latching portions 320 are annular slots defined in the first ends of the circumferences of the positioning poles 302 to receive sidewalls bounding the first and second through holes 182 and 184. In another embodiment, the latching portion 320 can be two opposite hooks each having a projection extending away from the other hook. The hooks can be deformed toward each other to extend through the first and second through holes 182 and 184 to allow the projections to abut an inner surface of the board 12, thereby mounting the fastener 30 to the board 12.

Each fan assembly 20 includes a frame 24 and a plurality of fans 22 received in the frame 24.

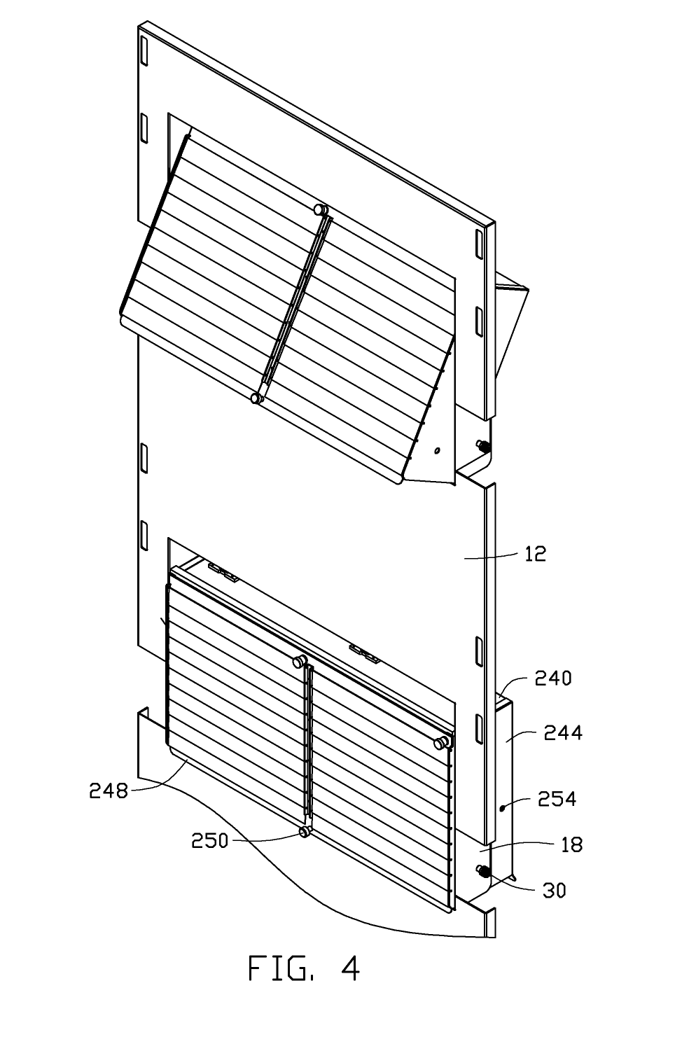

Referring to FIGS. 1 and 4, the frame 24 includes a top wall 240, a bottom wall 242, and two sidewalls 244 connected between corresponding ends of the top and bottom walls 240 and 242. A front plate 246 slantingly extends down and forward from a front side of the bottom wall 242. A rear plate 248 extends down from the rear side of the bottom wall 242 opposite to the front plate 246. A handle 250 is mounted to a rear surface of the rear plate 248. A pin 252 extends out from each sidewall 244, adjacent to a top end of the corresponding sidewall 244. A first threaded hole 254 is defined in each sidewall 244 adjacent to a middle of a front side of the sidewall 244. A second threaded hole 256 is defined in each sidewall 244 adjacent to a bottom end of a rear side of the sidewall 244.

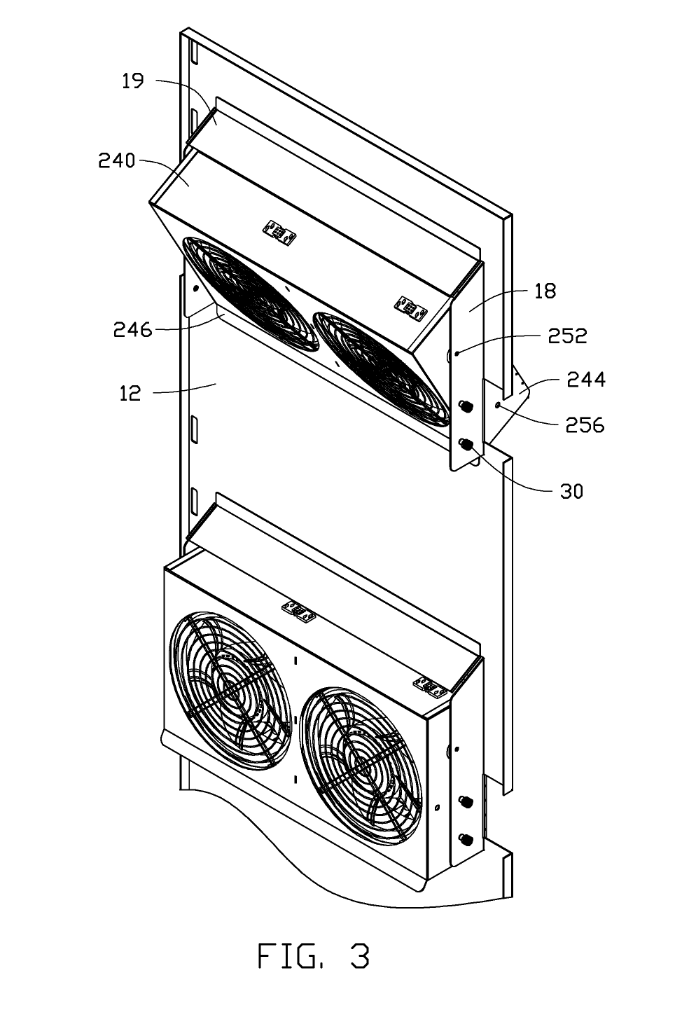

Referring to FIGS. 3 and 4, in assembly, the pins 252 of each frame 24 are pivotably inserted into two opposite pivot holes 180, to pivotably mount the corresponding fan assembly 20 in the corresponding opening 14.

If keeping a fan assembly 20 positioned slantingly, the handle 250 is pulled up and rearward to move a bottom of the fan assembly 20 up and rearward, until the first threaded holes 254 align with the corresponding first through holes 182. The heads 300 of the fasteners 300 mounted to the first through holes 182 are pushed toward the corresponding installation pieces 18 and are rotated, the heads 300 gently receive the corresponding positioning poles 302, the springs 304 are gently deformed, and distal ends of the threaded poles 306 are engaged in the corresponding first threaded holes 254. Thus, the fan assembly 20 is slanting relative to the board 12. At this time, the top wall 240 contacts the corresponding cover 19, to prevent airflow return. The front plate 246 abuts a front side of the board 12.

In vertically keeping one of the fan assemblies 20, the heads 300 of the fasteners 30 mounted to the first through holes 182 are rotated away from the corresponding installation pieces 182, to disengage the threaded poles 306 from the corresponding first threaded holes 254. The springs 304 are restored and push the corresponding heads 300 to move away from the installation pieces 182. The fan assembly 20 drops down under the gravitation, until the rear plate 248 abuts a rear surface of the board 12. At this time, the second threaded holes 256 are respectively aligned with the second through holes 184. The heads 300 of the fasteners 300 mounted to the second through holes 184 are pushed toward the corresponding installation pieces 18 and are rotated to screw the corresponding threaded poles 306 into the corresponding second threaded holes 256, thereby keeping the fan assembly 20 in a vertical direction.

A screwdriver can engage in the recess 314 to fix the fasteners 30 if needed.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A fan device, comprising:
a board defining an opening, two installation pieces extending from the board at opposite sides of the opening, one of the installation pieces defining a first through hole;
a fan assembly comprising a frame pivotably mounted between the installation pieces and in the opening, and a fan received in the frame; the frame comprising a top wall, a bottom wall, and two sidewalls connected between corresponding ends of the top and bottom walls, wherein one of the sidewalls adjacent to the installation piece defining the first through hole defines a first threaded hole; and
a first fastener;
wherein the first through hole is aligned with the first threaded hole and the first fastener extends through the first through hole to be engaged in the first threaded hole to fix the fan assembly to the board after the fan assembly is pivoted and slanting relative to the board.

2. The fan device of claim 1, wherein the first fastener comprises a head defining a receiving space, a positioning pole slidably received in the receiving space and defining a through slot extending through opposite ends of the positioning pole, and a threaded pole mounted to a blind end of the receiving space and extending into the receiving slot, the positioning pole comprises a latching portion at an end away from the head to engage with the board, wherein the positioning pole enters the receiving space, and the threaded pole extends out of the through slot to engage in the first threaded hole, in response to the head being pushed toward the corresponding installation piece and rotated.

3. The fan device of claim 2, wherein the first fastener further comprises a spring mounted to the blind end of the receiving space and fitted around the threaded pole.

4. The fan device of claim 2, wherein the latching portion is an annular slot defined in a circumference of the positioning pole.

5. The fan device of claim 1, wherein a front plate extending down and forward from a front side of the bottom wall, the front plate is abutted against a front surface of the board in response to the fan assembly being slantingly related to the board.

6. The fan device of claim 1, further comprising a second fastener, wherein one of the installation piece defines a second through hole, the sidewall adjacent to the installation piece defining the second through hole defines a second threaded hole, the second threaded hole is aligned with the second through hole, in response to the fan assembly being positioned in a direction in which the board extends, the second fastener extends through the second through hole to be engaged in the second threaded hole.

7. The fan device of claim 6, wherein each of the first and second fasteners comprises a head defining a receiving space, a positioning pole slidably received in the receiving space and defining a through slot extending through opposite ends of the positioning pole, and a threaded pole mounted to a blind end of the receiving space and extending into the receiving slot, the positioning pole comprises a latching member at an end away from the head to engage with the board, wherein the positioning pole enters the receiving space, and the threaded pole extends out of the through slot, in response to the head being pushed toward the corresponding installation piece and rotated.

8. The fan device of claim 7, wherein each fastener further comprises a spring mounted to the blind end of the receiving space and fitted around the threaded pole.

9. The fan device of claim 6, wherein a rear plate extends down from a rear side of the bottom wall to abut a rear surface of the board in response to the fan assembly being positioned in a direction in which the board extends.

10. The fan device of claim 1, wherein two pins extend out from the sidewalls of the frame to be pivotably inserted into the installation pieces.

11. The fan device of claim 2, wherein a cover slantingly extends down and forward from the board and at a top side of the opening, to contact the top wall of the frame in response to the fan assembly being slanting relative to the board.
